(19) United States
(12) Patent Application Publication
(10) Pub. No.: US 2023/0387665 A1
(43) Pub. Date: Nov. 30, 2023

(54) HIGH-POWER EDGE-EMITTING SEMICONDUCTOR LASER WITH ASYMMETRIC STRUCTURE

(71) Applicant: ARIMA LASERS CORP., TAOYUAN CITY (TW)

(72) Inventors: JIN YUAN HSING, TAOYUAN CITY (TW); JUNG MIN HWANG, TAOYUAN CITY (TW); CHEN YU CHIANG, TAOYUAN CITY (TW)

(21) Appl. No.: 17/825,587

(22) Filed: May 26, 2022

(51) Int. Cl. H01S 5/343; H01S 5/026

(52) U.S. Cl. CPC H01S 5/34313; H01S 5/34346; H01S 5/026

(57) ABSTRACT

A high-power edge-emitting semiconductor laser with asymmetric structure, comprising: a substrate layer; a lower cladding layer; a lower optical waveguide layer; a first lower barrier layer; a quantum well layer; a first upper barrier layer; an upper optical waveguide layer, and make the thickness of the upper optical waveguide layer be below 300 nm, the thickness of the upper optical waveguide layer is ⅓˜½ of the thickness of the lower optical waveguide layer; an upper cladding layer, and make the thickness of the upper cladding layer be below 900 nm, the thickness of the upper cladding layer is ⅓˜½ of the thickness of the lower cladding layer; and an ohmic contact layer formed on the upper cladding layer.

### BACKGROUND OF THE INVENTION

### 1. Field of the Invention

The invention relates to a high-power edge-emitting semiconductor laser with asymmetric structure, especially the one that uses an asymmetric structure to deviate the position of the active area closer to the upper cladding layer.

### 2. Description of the Related Art

The 976 nm semiconductor laser can be used as the excitation light source for Erbium-Doped Fiber Amplifiers (EDFA), the laser light can obtain 480˜490 nm blue-green light output through crystal frequency doubling, which is a new trend in the development of blue-green light sources; aluminum-free light emitting layer structure is used in 780˜980 nm semiconductor lasers, such as InGaAs, InGaAsP, GaAs, GaAsP, and its biggest advantage is that the entire light-emitting layer structure can against the catastrophic optical mirror damage (COMD) better than aluminum-containing epitaxy structure, as shown in the below table of J.

Jiménez, C. R. Physique 4 (2003) collated for COMD level for each material.

| | Emission | COMD level |
|---|---|---|
| Active region compound | wavelength (mm) | (MW/cm²) |
| InGaAs | 920-980 | 18-19 |
| InGaAsP | 810 | 18-19 |
| InAlGaAs | 810 | 13 |
| GaAs | 810-870 | 11-12 |
| GaAsP | 810 | 11 |
| AlGaAs ([Al] = 0.07) | 810 | 8 |
| AlGaAs ([Al] = 0.13) | 780 | 5 |

When the laser emitting wavelength is 976 nm, the quantum well energy gap of the light-emitting layer becomes smaller, and an epitaxial material structure with InGaAs as the quantum well (QW) can be used. At this time, the QW barrier waveguide system materials can use InGaAs/AlGaAs/AlGaAs, InGaAs/InGaAsP/GaInP or InGaAs/GaAsP/GaInP, to achieve high efficiency (wall-plug efficiency) requirements, InGaAs/AlGaAs/AlGaAs can be used to overcome the electrical power loss associated with the voltage increase during operating, so the conventional 976 nm high-power semiconductor laser uses the InGaAs/AlGaAs/AlGaAs material system, it has the advantages that the thermal conductivity of AlGaAs is higher than that of GaInP, low starting voltage, but the Al-containing layer is easily oxidized, the oxidation of the laser mirror surface will cause COMD, thereby reducing the reliability of the device. In addition, the InGaAs/InGaAsP/GalnP material system has the advantages of low starting voltage and high COMD level, but the surface topography of GaInP and InGaAsP epitaxial has a strong correlation with the crystal orientation angle of the GaAs substrate, and GaInP is suitable for growing on high-angle substrates, InGaAsP are suitable for growing on substrates at 0˜2 degrees, and the quaternary material InGaAsP are grown must precisely control the two five groups of gases, As/P. Therefore, the epitaxial growth technology of high-quality InGaAsP/InGaP has high requirements and is not easy to grow a high-quality epi-wafer.

The use of InGaAs/GaAsP/GalnP for 976 nm semiconductor lasers is better than InGaAs/GaAs/GaInP, because when the In content is higher, the high stress quantum wells are easy to cause defects to the film; GaAsP can reduce the compressive strain of the entire active area, reduce the defect density of QW, and increase the P content of GaAsP appropriately, the barrier height will increase, more electrons are confined to the QW, and the photoluminescence strength of the material can be increased, improve device performance (such as reducing drive current and improving slope efficiency (SE)), and GaAsP is a low-refractive index material, which can weaken the waveguide confinement effect, thereby increasing the near-field width and reducing the vertical far-field angle. In addition, by inserting several nanometers of GaAs into the InGaAs/GaAsP interface, the light type is not affected, but the diffusion of In atoms into GaAsP can be prevented, and the formation of interdiffused quaternary compound layers (InGaAsP) at the InGaAs/GaAsP interface can be avoided, reducing the component performance.

When the length of the resonant cavity of the laser element is increased to 2˜6 mm, the injected current density can be effectively reduced, and the area of heat dissipation can be incrcased at the same time, thereby reducing the junction temperature of the element; but the internal loss increases as the cavity lengthens, resulting in a decrease in SE.

### SUMMARY OF THE INVENTION

It is a primary objective of the present invention is to provide a high-power edge-emitting semiconductor laser with asymmetric structure, and having the effect of improving the output optical power by using the asymmetric structure.

Another objective of the present invention is to use aluminum-free active area to increase the COMD level, and having the effect of increasing the reliability of elements.

In order to achieve the above objectives, the high-power edge-emitting semiconductor laser with asymmetric structure, includes: a substrate layer, the material is n-type gallium arsenide (n-GaAs); a lower cladding layer, the material is n-type aluminum gallium indium phosphide (n-AlxGal-xInP, x is 0.2˜0.4) and formed on the substrate layer; a lower optical waveguide layer, the material is gallium indium phosphide (GaInP) and formed on the lower cladding layer; a first lower barrier layer, the material is gallium arsenide phosphide (GaAsP) and formed on the lower optical waveguide layer; a quantum well layer, the material is indium gallium arsenide (InGaAs) and formed on the first lower barrier layer; a first upper barrier layer, the material is gallium arsenide phosphide (GaAsP) and formed on the quantum well layer; an upper optical waveguide layer, the material is gallium indium phosphide (GalnP) and formed on the first upper barrier layer, and make the thickness of the upper optical waveguide layer be below 300 nm, the thickness of the upper optical waveguide layer is ⅓˜½ of the thickness of the lower optical waveguide layer; an upper cladding layer, the material is p-type aluminum gallium indium phosphide (p-AlxGal-xInP, x is 0.55˜0.9) and formed on the upper optical waveguide layer, and make the thickness of the upper cladding layer be below 900 nm, the thickness of the upper cladding layer is ⅓˜½ of the thickness of the lower cladding layer; and an ohmic contact layer, the material is p-type gallium arsenide (p-GaAs) and formed on the upper cladding layer.

Also, a second lower barrier layer made of gallium arsenide (GaAs) is formed between the quantum well layer and the first lower barrier layer, and a second upper barrier layer made of gallium arsenide (GaAs) is formed between the quantum well layer and the first upper barrier layer.

Also, a lower transition layer made of n-type gallium indium phosphide (n-GalnP) is also formed between the substrate layer and the lower cladding layer, and an upper transition layer made of layer p-type gallium indium phosphide (p-GalnP) is also formed between the upper cladding layer and the ohmic contact layer.

Also, the material of the lower transition layer is n-Ga0.51In0.49P, the thickness of the lower cladding layer is 2200 nm and the material is n-(Al0.2Ga0.8)In0.5P, the thickness of the lower optical waveguide layer is 800 nm and the material is Ga0.51In0.49P, the material of the first lower barrier layer is Ga0.8AsP0.2, the second lower barrier layer thickness is 2˜5 nm, the material of the quantum well layer is In0.2Ga0.8As and the thickness of the quantum well layer is 5˜10 nm, the thickness of the second upper barrier layer is 2˜5 nm, the material of the first upper barrier layer is Ga0.8AsP0.2, the thickness of the upper optical waveguide layer is 300 nm and the material is Ga0.51In0.49P, the thickness of the upper cladding layer is 845 nm and the material is p-(A10.65Ga0.35)In0.5P, and the material of the upper transition layer is p-Ga0.51In0.49P Also, a lower transition layer made of n-type gallium indium phosphide (n-GalnP) is also formed between the substrate layer and the lower cladding layer, and an upper transition layer made of layer p-type gallium indium phosphide (p-GaInP) is also formed between the upper cladding layer and the ohmic contact layer. And the crystal orientation angle of the substrate layer deviates for (100) 10 degrees.

Whereby, the thickness of the upper optical waveguide layer is smaller than the thickness of the lower optical waveguide layer, and the thickness of the upper cladding layer is smaller than the thickness of the lower cladding layer, the position of the active area is shifted to be close to the upper cladding layer, and the output optical power can be improved structurally.

### BRIEF DESCRIPTION OF THE DRAWINGS

FIG. 1 is a schematic diagram of the structure of the present invention;

FIG. 2 is a schematic diagram illustrating f of the correlation between various asymmetric structures of the present invention and the light intensity rate in area other than P-type doping.

### DETAILED DESCRIPTION OF THE PREFERRED EMBODIMENT

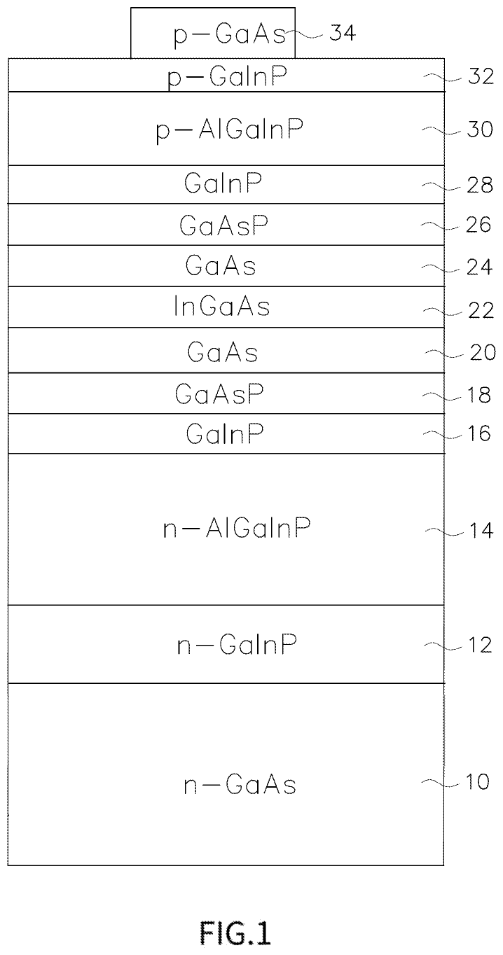

Referring to FIG. 1, the present invention from bottom to top are: n-GaAs substrate layer 10, n-Ga_{0.51}In_{0.49}P lower transition layer 12, n-(Al_{0.2}Ga_{0.8})In_{0.5}P lower cladding layer 14 with a thickness of 2200 nm, Ga_{0.51}In_{0.49}P lower optical waveguide layer 16 with a thickness of 800 nm, Ga_{0.8}AsP_{0.2} first lower barrier layer 18, GaAs second lower barrier layer 20 with thickness of 2˜5 nm, In_{0.2}Ga_{0.8} quantum well layer 22 with thickness of 5-10 nm, GaAs second upper barrier layer 24 with thickness of 2-5 nm, Ga_{0.8}AsP_{0.2} first upper barrier layer 26, Ga_{0.51}In_{0.49}P upper optical waveguide layer 28 with thickness of 300 nm, p-(Al_{0.65}Ga_{0.35})In_{0.5}P upper cladding layer with a thickness of 845 nm, p-Ga_{0.51}In_{0.49}P upper transition layer 32 and a p-GaAs ohmic contact layer 34.

With the features disclosed above, the present invention is a 976 nm high-power semiconductor laser with an asymmetric structure without aluminum active area, the material epitaxial part is grown on the GaAs substrate layer 10 with a deviation (100) from the crystal orientation angle of degrees, and the active area stress compensation structure is inserted with 2˜5 nm barrier layers 20,24, the PL wavelength of the quantum well layer 22 is designed at 965 nm, and under high current, the electroluminescence (EL) wavelength corresponding to this photoluminescence (PL) wavelength can reach 976 nm; Therefore, by adjusting the different thicknesses of the upper and lower optical waveguide layers 28, 16 and the different compositions and thicknesses of the upper and lower cladding layers 30, 14, make more than 90% of the optical field falls outside the area of the p-doping, the internal loss is minimized, and the thermal resistance of the device in high-power operation is reduced by shortening the thickness of the P-type doped side;

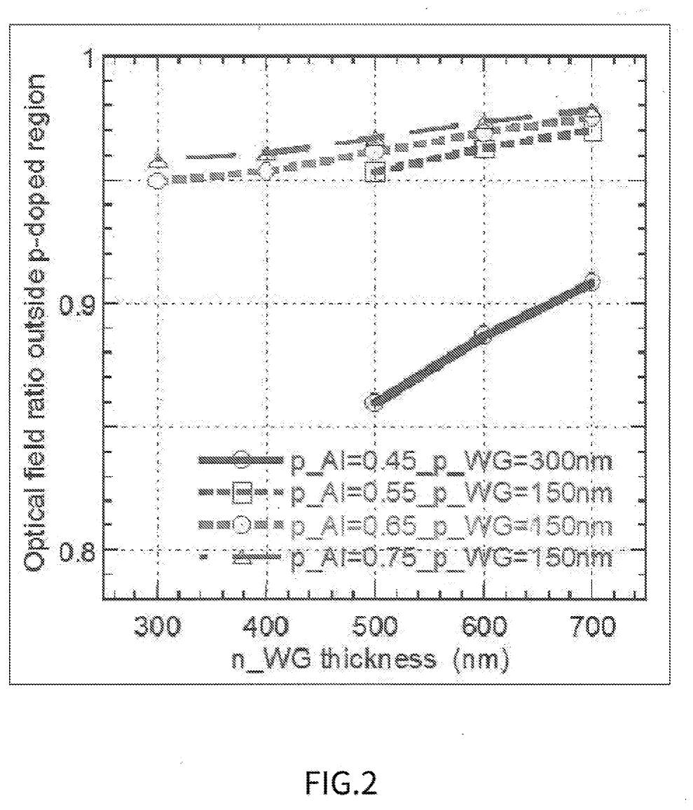

FIG. 2 is showing the thickness of the upper optical waveguide layer 28 with a thickness of 150 nm or 300 nm and the upper cladding layer 30 with different aluminum compositions corresponds to the lower optical waveguide layer 16 with a thickness of 800 nm, and the proportion of the optical field outside the area of p-doping is≥93%.

The present invention introduces an asymmetric decoupled confinement heterostructure (ADCH) structure to reduce internal loss and increase SE; the thickness of the upper optical waveguide layer 28 is smaller than the thickness of the lower optical waveguide layer 16, and the thickness of the upper cladding layer 30 is smaller than the thickness of the lower cladding layer 14, so the position of the active area is shifted to be close to the upper cladding layer 30, the refractive index of the lower cladding layer 14 is higher than that of the upper cladding layer 30, which can greatly reduce the optical field absorbing by the free carriers falling on the upper cladding layer 30, and the optical confinement factor Γ_{p-WG}<Γ_{n-WG} and Γ_{QW} becomes smaller and the equivalent light spot becomes larger, according to the following formula Pₘₐₓ=(d_{qw}/Γ_{qw})*W*[1−R/(1+R)]*P_{COMD}(Pₘₐₓ: maximum output power, d_{qw}: quantum well width, Γ_{qw}: confinement factor, R: front mirror surface specular reflectance, P_{COMD}: maximum output power that can withstand from COMD) can be structurally improving the output optical power, and has the effect of using the asymmetric structure to improve the output optical power; at the same time, the active area is Al-free material, which also helps to improve the COMD level, which has the effect of increasing the reliability of the components.

Although particular embodiments of the invention have been described in detail for purposes of illustration, various modifications and enhancements may be made without departing from the spirit and scope of the invention.

Accordingly, the invention is not to be limited except as by the appended claims.

What is claimed is:

1. A high-power edge-emitting semiconductor laser with asymmetric structure, comprising:
a substrate layer 10, the material is n-type gallium arsenide (n-GaAs);
a lower cladding layer 14, the material is n-type aluminum gallium indium phosphide (n-AlxGal-xInP, x is 0.2˜0.4)and formed on the substrate layer 10;
a lower optical waveguide layer 16, the material is gallium indium phosphide (GalnP) and formed on the lower cladding layer 14;
a first lower barrier layer 18, the material is gallium arsenide phosphide (GaAsP) and formed on the lower optical waveguide layer 16;
a quantum well layer 22, the material is indium gallium arsenide (InGaAs) and formed on the first lower barrier layer 18;
a first upper barrier layer 26, the material is gallium arsenide phosphide (GaAsP) and formed on the quantum well layer 22;
an upper optical waveguide layer 28, the material is gallium indium phosphide (GalnP) and formed on the first upper barrier layer 26, and make the thickness of the upper optical waveguide layer 28 be below 300 nm, the thickness of the upper optical waveguide layer 28 is ⅓˜½ of the thickness of the lower optical waveguide layer 16;
an upper cladding layer 30, the material is p-type aluminum gallium indium phosphide (p-AlxGal-xInP, x is 0.55˜0.9) and formed on the upper optical waveguide layer 28, and make the thickness of the upper cladding layer 30 be below 900 nm, the thickness of the upper cladding layer 30 is ⅓˜½ of the thickness of the lower cladding layer 14; and
an ohmic contact layer 34, the material is p-type gallium arsenide (p-GaAs) and formed on the upper cladding layer 30.

2. The high-power edge-emitting semiconductor laser with asymmetric structure, as claimed in claim 1, wherein a second lower barrier layer 20 made of gallium arsenide (GaAs) is formed between the quantum well layer 22 and the first lower barrier layer 18, and a second upper barrier layer 24 made of gallium arsenide (GaAs) is formed between the quantum well layer 22 and the first upper barrier layer 26.

3. The high-power edge-emitting semiconductor laser with asymmetric structure, as claimed in claim 1, wherein a lower transition layer 12 made of n-type gallium indium phosphide (n-GalnP) is also formed between the substrate layer 10 and the lower cladding layer 14, and an upper transition layer 32 made of layer p-type gallium indium phosphide (p-GaInP) is also formed between the upper cladding layer 30 and the ohmic contact layer 34.

4. The high-power edge-emitting semiconductor laser with asymmetric structure, as claimed in claim 3, wherein the material of the lower transition layer 12 is n-Ga0.51In0.49P, the thickness of the lower cladding layer 14 is 2200 nm and the material is n-(Al0.2Ga0.8)In0.5P, the thickness of the lower optical waveguide layer 16 is 800 nm and the material is Ga0.5In0.49P, the material of the first lower barrier layer 18 is Ga0.8AsP0.2, the second lower barrier layer 20 thickness is 2˜5 nm, the material of the quantum well layer 22 is In0.2Ga0.8As and the thickness of the quantum well layer 22 is 5˜10 nm, the thickness of the second upper barrier layer 24 is 2˜5 nm, the material of the first upper barrier layer 26 is Ga0.8AsP0.2, the thickness of the upper optical waveguide layer 28 is 300 nm and the material is Ga0.51In0.49P, the thickness of the upper cladding layer 30 is 845 nm and the material is p-(Al0.65Ga0.35)In0.5P, and the material of the upper transition layer 32 is p-Ga0.51In0.49P

5. The high-power edge-emitting semiconductor laser with asymmetric structure, as claimed in claim 1, wherein the crystal orientation angle of the substrate layer 10 deviates for (100) 10 degrees.
